(19) United States
(12) Patent Application Publication
(10) Pub. No.: US 2026/0293600 A1
(43) Pub. Date: Sep. 24, 2026

(54) ELECTROSTATIC CHUCK

(71) Applicant: TOTO LTD., Fukuoka (JP)

(72) Inventors: Yuki SASAKI, Fukuoka (JP); Jun SHIRAISHI, Fukuoka (JP); Ikuo ITAKURA, Fukuoka (JP); Kensuke SUZUKI, Fukuoka (JP)

(73) Assignee: TOTO LTD., Fukuoka (JP)

(21) Appl. No.: 19/544,374

(22) Filed: Feb. 19, 2026

(30) Foreign Application Priority Data
Mar. 18, 2025 (JP) 202543309

(51) Int. Cl. H10P 72/72

(52) U.S. Cl. CPC H10P 72/722

(57) ABSTRACT

An electrostatic chuck 10 includes a dielectric substrate 100 including a surface 110 on which a wafer W is placed, and an RF electrode layer 140 provided inside the dielectric substrate 100. In a cross-section obtained by cutting the RF electrode layer 140 along a plane perpendicular to the surface 110, a void density calculated as the number of voids 40 per unit area is equal to or larger than 1500/mm² in the electrostatic chuck 10.

### CROSS-REFERENCE TO RELATED APPLICATION

This application is based upon and claims the benefit of priority from Japanese Patent Application No. 2025-043309 filed on March 18, 2025, the entire contents of which are incorporated herein by reference.

### Field

The present invention relates to an electrostatic chuck.

### Background

For example, in a semiconductor manufacturing apparatus such as an etching apparatus, an electrostatic chuck is provided as an apparatus configured to attract and hold a wafer such as a silicon wafer to be processed. The electrostatic chuck includes a dielectric substrate provided with an attraction electrode. When a voltage is applied to the attraction electrode, an electrostatic force is generated, and the wafer placed on the dielectric substrate is attracted and held. The attraction electrode is often provided inside the dielectric substrate as an attraction electrode layer.

As described in Japanese Patent Laid-Open No. 2011-119654, an RF electrode layer may be provided inside the dielectric substrate in addition to the attraction electrode layer. The RF electrode layer is a conductor layer provided as one of a pair of counter electrodes for generating plasma in the semiconductor manufacturing apparatus. The other of the counter electrodes is provided at a position on an upper side relative to the electrostatic chuck in the semiconductor manufacturing apparatus.

### SUMMARY

In the RF electrode layer, a relatively large current flows. Due to Joule heat and the like generated by the current, stress is applied to the RF electrode layer. If the stress becomes excessively large, there is a possibility that peeling or the like of the RF electrode layer may occur at an interface between the RF electrode layer and the dielectric substrate.

The present invention has been made in view of such problems, and an object thereof is to provide an electrostatic chuck capable of relaxing stress applied to an RF electrode layer.

To address the above-described problems, the electrostatic chuck according to the present invention includes a dielectric substrate including a placement surface on which an object to be attracted is placed, and an RF electrode layer provided inside the dielectric substrate. In this electrostatic chuck, in a cross-section obtained by cutting the RF electrode layer along a plane perpendicular to the placement surface, a void density calculated as the number of voids per unit area is equal to or larger than 1500/mm².

In the electrostatic chuck having the above-described configuration, the void density inside the RF electrode layer is increased to be equal to or larger than 1500/mm². With such a configuration, stress applied to the RF electrode layer can be relaxed by a large number of voids arranged inside the RF electrode layer. As a result, peeling or the like at an interface between the RF electrode layer and the dielectric substrate can be prevented.

According to the present invention, it is possible to provide an electrostatic chuck capable of relaxing stress applied to an RF electrode layer.

### BRIEF DESCRIPTION OF THE DRAWINGS

FIG. 1 is a cross-sectional view schematically illustrating a configuration of an electrostatic chuck according to the present embodiment; and

FIG. 2 is a cross-sectional view illustrating a configuration of an RF electrode layer.

### DETAILED DESCRIPTION

Hereinafter, the present embodiment will be described with reference to the accompanying drawings. For ease of understanding of the descriptions, in each drawing, the same components are denoted by the same reference signs as much as possible, and duplicate descriptions are not repeated.

An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W that is an object to be attracted is, for example, a silicon wafer. The electrostatic chuck 10 may be used in an apparatus other than the semiconductor manufacturing apparatus.

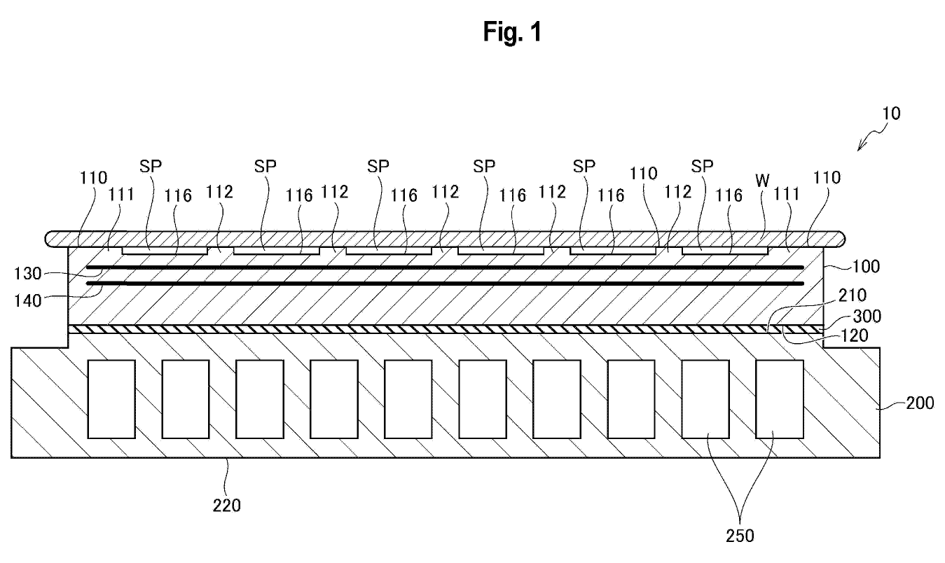

FIG. 1 is a cross-sectional view schematically illustrating a configuration of the electrostatic chuck 10 in a state in which the wafer W is attracted and held. The electrostatic chuck 10 includes a dielectric substrate 100 and a base plate 200.

The dielectric substrate 100 is a substantially disk-shaped member formed of a ceramic sintered body. The dielectric substrate 100 is formed of a material containing alumina (Al₂O₃) as a principal component. A ceramic purity or type, an additive, or the like in the dielectric substrate 100 may be appropriately set by taking into account plasma resistance or the like required for the dielectric substrate 100 in the semiconductor manufacturing apparatus.

A surface 110 on an upper side in FIG. 1 in the dielectric substrate 100 serves as a "placement surface" on which the wafer W, as a process target, is placed. A surface 120 on a lower side in FIG. 1 in the dielectric substrate 100 serves as a "surface to be joined" which is joined to the base plate 200 via a joining layer 300. A perspective in a case where the electrostatic chuck 10 is viewed from the surface 110 side along a direction perpendicular to the surface 110 will also be hereinafter expressed as "top view".

An attraction electrode layer 130 is embedded inside the dielectric substrate 100. The attraction electrode layer 130 is a thin planar layer made of a metallic material such as, for example, palladium, and is arranged to be parallel to the surface 110. As a material of the attraction electrode layer 130, molybdenum, platinum, tungsten, and the like may be used in addition to palladium. When a voltage is applied to the attraction electrode layer 130 from an outside via a feed line which is not illustrated in the drawing, an electrostatic force is generated between the surface 110 and the wafer W, and according to this, the wafer W is attracted and held. As a configuration of the above-described feed line, various configurations in related art can be adopted. The single attraction electrode layer 130 may be provided as a so-called "monopolar" electrode as in the present embodiment, but two attraction electrode layers 130 may also be provided as so-called "bipolar" electrodes.

In addition to the above-described attraction electrode layer 130, an RF electrode layer 140 is embedded inside the dielectric substrate 100. The RF electrode layer 140 is provided as one of a pair of counter electrodes for generating plasma in the semiconductor manufacturing apparatus. The other of the counter electrodes is provided at a position on an upper side relative to the electrostatic chuck 10 in the semiconductor manufacturing apparatus. When a high-frequency alternating-current voltage is applied between these counter electrodes, plasma is generated on the upper side of the wafer W and used for a process such as film deposition and etching on the wafer W.

As in the attraction electrode layer 130, the RF electrode layer 140 is a thin planar layer made of a metallic material containing palladium as a principal component. As a material of the RF electrode layer 140, molybdenum, platinum, tungsten, and the like may be used in addition to palladium.

The RF electrode layer 140 is embedded at a position closer to the surface 120 side than the attraction electrode layer 130. As in the attraction electrode layer 130, the RF electrode layer 140 is arranged to be parallel to the surface 110. The RF electrode layer 140 is a single electrode which is substantially circular in top view. In top view, a center of the RF electrode layer 140 matches a center of the dielectric substrate 100.

A voltage is applied to the RF electrode layer 140 via a feed line which is not illustrated in the drawing. The feed line may be connected to an external power source, for example, through a through hole formed in the base plate 200 described later, and may be electrically connected to a metal portion of the base plate 200. As a configuration of the above-described feed line, various configurations in related art can be adopted.

A space SP is formed between the dielectric substrate 100 and the wafer W. When a process such as etching is performed in the semiconductor manufacturing apparatus, helium gas for temperature regulation is supplied to the space SP from the outside via a gas hole which is not illustrated in the drawing. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. The seal ring 111 is an annular protrusion formed on the surface 110 side. A distal end (upper end in FIG. 1) of the seal ring 111 serves as a part of the surface 110 and abuts against the wafer W. The distal end of the seal ring 111 can be referred to as a part on an outermost circumferential side on the surface 110 which serves as the placement surface.

It is noted that the seal ring 111 may include a plurality of seal rings 111 provided to divide the space SP. With such a configuration, a pressure of the helium gas in each of the spaces SP can be individually regulated, and a surface temperature distribution of the wafer W during the process can be set to be close to uniformity.

A part denoted by reference sign "116" in FIG. 1 is a bottom of the space SP. Hereinafter, this part may also be referred to as a "bottom 116". The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. An upper end of each of the dots 112 becomes a part of the surface 110 and abuts against the wafer W. By providing the plurality of such dots 112, warping of the wafer W is reduced.

The base plate 200 is a substantially disk-shaped member which supports the dielectric substrate 100. The base plate 200 is made of, for example, a metallic material such as aluminum. A surface 210 on the upper side in FIG. 1 in the base plate 200 serves as a "surface to be joined" which is joined to the dielectric substrate 100 via the joining layer 300.

The joining layer 300 is a layer provided between the dielectric substrate 100 and the base plate 200 to join those components. The joining layer 300 is obtained by causing an adhesive made of an insulating material to be cured. In the present embodiment, a silicone adhesive is used as the above-described adhesive. It is noted however that the joining layer 300 may be obtained by causing an adhesive of other types to be cured. In any case, in order that a thermal resistance between the dielectric substrate 100 and the base plate 200 is reduced, a material with a highest possible thermal conductivity is preferably used as the material of the joining layer 300.

An insulating film may be formed on a surface of the base plate 200. As the insulating film, for example, an alumina film formed by thermal spraying can be used. When the surface of the base plate 200 is covered by the insulating film, it is possible to increase an insulation withstand voltage of the base plate 200.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 250 are performed via openings which are not illustrated in the drawing and which are formed in a surface 220 opposite to the surface 210 in the base plate 200.

When the process on the wafer W is being performed in the semiconductor manufacturing apparatus, a relatively large current flows in the RF electrode layer 140. Due to Joule heat and the like generated by the current, stress is applied to the RF electrode layer 140. If the stress becomes excessively large, there is a possibility that peeling or the like of the RF electrode layer 140 may occur at an interface between the RF electrode layer 140 and the dielectric substrate 100. Thus, in the electrostatic chuck according to the present embodiment, the above-described problem is to be addressed by devising an arrangement of voids included in the RF electrode layer 140.

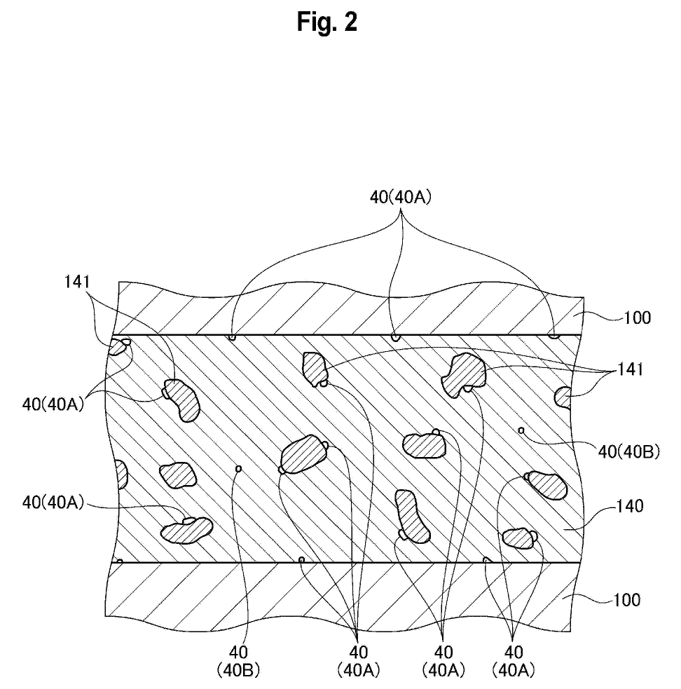

A configuration of the RF electrode layer 140 will be described. FIG. 2 illustrates a cross-section obtained by cutting the RF electrode layer 140 along a plane perpendicular to the placement surface (surface 110). As illustrated in FIG. 2, a plurality of ceramic particles 141 are arranged inside the RF electrode layer 140. The ceramic particles 141 are arranged for the purpose of preventing occurrence of warpage during firing of the dielectric substrate 100, and the like. The ceramic particles 141 may be particles formed of the same material as a material constituting the dielectric substrate 100 (alumina in the present embodiment), or may be particles formed of a ceramic material different from the material constituting the dielectric substrate 100.

In manufacturing the electrostatic chuck 10, the dielectric substrate 100 is formed by laminating a plurality of green sheets. The RF electrode layer 140 is formed by printing a paste-like material on surfaces of some of the green sheets before lamination. The ceramic particles 141 have been mixed in advance into the paste.

In the cross-section of the RF electrode layer 140 illustrated in FIG. 2, cross-sections of a plurality of voids 40 appear in addition to cross-sections of the plurality of ceramic particles 141. The number of the voids 40 per unit area in the cross-section of the RF electrode layer 140 illustrated in FIG. 2, specifically, a value calculated as the number of the voids 40 per 1 mm², is hereinafter also referred to as "void density". In the present embodiment, the RF electrode layer 140 is formed so that the void density is equal to or larger than 1500/mm². The same applies to a cross-section of the RF electrode layer 140 at a position not illustrated in FIG. 2.

By arranging a large number of voids 40 inside the RF electrode layer 140, overall elasticity of the RF electrode layer 140 is increased. With such a configuration, stress applied to the RF electrode layer 140 can be relaxed by the large number of voids 40 arranged inside the RF electrode layer 140. As a result, peeling or the like at an interface between the RF electrode layer 140 and the dielectric substrate 100 can be prevented.

As a value of the void density is increased, stress applied to the RF electrode layer 140 is reduced. If the void density is set to be equal to or larger than 2000/mm², more preferably equal to or larger than 3000/mm², and further preferably equal to or larger than 4000/mm², stress applied to the RF electrode layer 140 can be further relaxed.

However, if the void density of the RF electrode layer 140 becomes excessively large, there is a concern that an electric resistance of the RF electrode layer 140 becomes excessively large or a strength of the RF electrode layer 140 is lowered. For this reason, it is preferable that the void density of the RF electrode layer 140 be kept equal to or smaller than 20000/mm², more preferably equal to or smaller than 15000/mm².

In the present embodiment, a cross-sectional area of each of the voids 40 appearing in the cross-section of the RF electrode layer 140 is about 1 μm² even at a maximum. If the plurality of voids 40 include the void 40 having a large cross-sectional area, there is a concern that a thermal resistance of the dielectric substrate 100 locally increases at this portion, or that a strength of this portion locally decreases. For this reason, it is preferable to form the RF electrode layer 140 such that, among the plurality of voids 40 appearing in the cross-section of the RF electrode layer 140, a cross-sectional area of the largest void 40 is equal to or smaller than 10 μm².

Among the plurality of voids 40 illustrated in FIG. 2, the void 40 present at either an interface between the dielectric substrate 100 and the RF electrode layer 140 or an interface between each ceramic particle 141 and the RF electrode layer 140 is hereinafter also referred to as an "interface void 40A". The other voids 40 are hereinafter also referred to as "voids 40B". In the example illustrated in FIG. 2, most of the plurality of voids 40 are "interface voids 40A", and the number of the "voids 40B" is extremely small. Due to this, even in a case where the above-described void density is calculated excluding the voids 40B, the void density is equal to or larger than 1500/mm². In other words, in a case where the void density calculated as the number of the interface voids 40A per unit area in the cross-section of the RF electrode layer 140 illustrated in FIG. 2 is defined as an "interface void density", the interface void density in the present embodiment is equal to or larger than 1500/mm². The same applies to a cross-section of the RF electrode layer 140 at a position not illustrated in FIG. 2.

The void density and the interface void density can be adjusted depending on a shape, a size, and an arrangement density (the number per unit area), and the like of the ceramic particles 141 arranged in the RF electrode layer 140. For example, when the arrangement density of the ceramic particles 141 is increased, the void density and the like of the RF electrode layer 140 are also increased accordingly. Furthermore, as a circularity of a cross- section of the ceramic particle 141 is made smaller than 1 (that is, as the ceramic particle 141 has a distorted shape further deviating from a true circle), the void density of the RF electrode layer 140 can be increased, and a cross-sectional area per void 40 can be reduced.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be attracted is placed; and
an RF electrode layer provided inside the dielectric substrate, wherein
in a cross-section obtained by cutting the RF electrode layer along a plane perpendicular to the placement surface,
a void density calculated as the number of voids per unit area is equal to or larger than 1500/mm².

2. The electrostatic chuck according to claim 1, wherein the void density is equal to or smaller than 20000/mm².

3. The electrostatic chuck according to claim 1, wherein among the plurality of voids appearing in the cross-section, a cross-sectional area of the largest void is equal to or smaller than 10 μm².

4. The electrostatic chuck according to claim 1, wherein
a plurality of ceramic particles are arranged inside the RF electrode layer, and,
in the cross-section,
when the void present at either an interface between the dielectric substrate and the RF electrode layer or an interface between each ceramic particle and the RF electrode layer is defined as an interface void,
an interface void density calculated as the number of the interface voids per unit area in the cross-section is equal to or larger than 1500/mm².
